(19) United States
(12) Patent Application Publication
(10) Pub. No.: US 2026/0068654 A1
(43) Pub. Date: Mar. 5, 2026

(54) BEVELED INTERCONNECT

(71) Applicant: Texas Instruments Incorporated, Dallas, TX (US)

(72) Inventors: Jeffrey Alan West, Dallas, TX (US); Elizabeth Costner Stewart, Dallas, TX (US); Byron Lovell Williams, Plano, TX (US); Yoshihiro Takei, Tsukuba (JP); Takashi Sasaki, Ishioka (JP); Koichi Funada, Tsuchiura (JP)

(21) Appl. No.: 18/822,174

(22) Filed: Aug. 31, 2024

(51) Int. Cl. H01L 23/522; H01L 23/528

(52) U.S. Cl. CPC H01L 23/5223

(57) ABSTRACT

A microelectronic device including a beveled interconnect is disclosed. Example microelectronic devices include a dielectric layer having a first surface at a first height over a substrate, a second surface at a second height over the substrate, and a third surface connecting the first surface and the second surface. The first and third surfaces form a beveled corner. A beveled interconnect includes a first interconnect segment over the first surface and a second interconnect segment extending from the first interconnect segment toward the second surface and ending over the third surface.

### FIELD

This disclosure relates to the field of microelectronic devices, and more particularly, but not exclusively, to interconnects in microelectronic devices.

### BACKGROUND

Interconnects are conductive paths used in microelectronic devices. In certain applications such as a galvanic isolator, a dielectric may be between interconnects which may have large voltage differences between them. Galvanic isolation is a principle of isolating functional sections of electrical systems to prevent current flow while energy or information can still be exchanged between the sections by other means, such as capacitance, induction, electromagnetic waves, optical, acoustic, or mechanical means. Galvanic isolation is typically used where two or more electric circuits communicate, but their grounds or reference nodes may be at different potentials. It is an effective method of breaking ground loops by preventing unwanted current from flowing between two units sharing a reference conductor. Galvanic isolation is also used for safety as a means of preventing accidental current from reaching ground through a person's body.

Isolators are devices designed to minimize direct current and unwanted transient currents between two systems or circuits while allowing data and power transmission between the two. In most applications, isolators also act as a barrier to high voltage in addition to allowing the system to function properly. Dielectric material is commonly used to isolate elements in isolators. Where conductive elements are separated by dielectric material in isolators, dielectric breakdown is a key concern, especially in high-voltage applications.

As advances in the design of integrated circuits and semiconductor fabrication continue, improvements in microelectronic devices, including galvanic isolators are also being concomitantly pursued.

### SUMMARY

The following presents a simplified summary in order to provide a basic understanding of one or more aspects of the present patent disclosure. The summary is not an extensive overview of the disclosure and is not intended to identify key or critical elements of the disclosure, nor is it to delineate the scope thereof. Rather, the primary purpose of the summary is to present some concepts of the disclosure in a simplified form as a prelude to a more detailed description that is present later.

Example include microelectronic devices including a beveled interconnect. Example devices include a dielectric layer having a first surface at a first height over a substrate, a second surface at a second height over the substrate, and a third surface connecting the first surface and the second surface. The first and third surfaces form a beveled corner. A beveled interconnect includes a first interconnect segment over the first surface and a second interconnect segment extending from the first interconnect segment toward the second surface and ending over the third surface.

Further examples include methods of forming associated microelectronic devices.

### BRIEF DESCRIPTION OF THE VIEWS OF THE DRAWINGS

Examples of the present disclosure are illustrated by way of example, and not by way of limitation, in the Figures of the accompanying drawings in which like references indicate similar elements. It should be noted that different references to “an” or “one” example in this disclosure are not necessarily to the same example, and such references may mean at least one. Further, when a particular feature, structure, or characteristic is described in connection with an example, it is submitted that it is within the knowledge of one skilled in the art to affect such feature, structure, or characteristic in connection with other examples whether or not explicitly described.

The accompanying drawings are incorporated into and form a part of the specification to illustrate one or more examples of the present disclosure. Various advantages and features of the disclosure will be understood from the following detailed description taken in connection with the appended claims and with reference to the attached drawing Figures in which:

FIG. 1A is a cross section of an example microelectronic device in which a bottom corner of an interconnect is beveled.

FIG. 1B is a cross section of an example microelectronic device containing a beveled interconnect in which two bottom corners of the beveled interconnect are beveled.

FIG. 2A is a perspective view of an example microelectronic device including an inductive isolation device containing a top metal coil implemented by a beveled interconnect.

FIG. 2B-FIG. 2K are cross sections of an example method of formation of a microelectronic device including an isolation device in which an outermost bottom edge of the top isolation element contains a beveled interconnect.

FIG. 3A is a cross section of an example microelectronic device including an isolation device in which both the outermost bottom edge and the innermost bottom edge of the top isolation element contain a beveled interconnect.

FIG. 3B is an inset of FIG. 3A showing a more detailed cross-sectional view of an example microelectronic device including an isolation device in which both the outer most bottom edge and the inner most bottom edge of the top isolation element contain a beveled interconnect.

FIG. 4A is a cross section of an example microelectronic device including an isolation device in which all of interconnects of the top isolation element includes beveled interconnects.

FIG. 4B is an inset of FIG. 4A showing a more detailed cross-sectional view of an example microelectronic device including an isolation device in which all of interconnects of the top isolation element include beveled interconnects.

FIG. 5 is a cross section of an example microelectronic device including an galvanic isolation capacitor including a beveled interconnect as a top metal plate of the capacitor.

FIG. 6 is a graph of maximum electric field simulations showing a reduction in maximum electric field produced at a corner of a beveled interconnect compared to a sharp (e.g. 90°) corner of a non-beveled interconnect.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while various examples are directed to active devices, it is not intended that these illustrations be a limitation on the scope or applicability of the present disclosure. It is not intended that active devices otherwise within the scope of the disclosure be limited to the physical structures illustrated. Such structures are included to demonstrate the utility and application of the described examples.

Example microelectronic devices described below may include or be formed of a semiconductor material like silicon (Si), silicon carbide (SiC), silicon germanium (SiGe), gallium arsenide (GaAs), or an organic semiconductor material. The semiconductor material may be embodied as a semiconductor wafer. The microelectronic devices include one or more galvanic isolation devices. The microelectronic devices may also include one or more semiconductor component or components such as metal oxide semiconductor field effect transistors (MOSFETs), insulated gate bipolar transistors (IGBTs) gate drivers, input/output and control circuitry, microprocessors, microcontrollers, and/or micro-electro-mechanical components or systems (MEMS). The microelectronic devices may be manifested as single chip devices or may be contained in multi-chip modules (MCMs). The semiconductor chip may further include inorganic and/or organic materials that are not semiconductor, for example, insulators such as inorganic dielectric materials or polymers, or conductors such as metals.

For the purposes of this disclosure, the term “high voltage” refers to operating potentials greater than 450 volts, and “low voltage” refers to operating potentials less than 100 volts. For example, a high voltage portion of the isolation device may operate at 450 volts to 1500 volts, while a low voltage portion of the isolation device may operate at 1.5 volts to 30 volts.

It is noted that terms such as top, bottom, front, back, over, above, under, and below may be used in this disclosure. These terms should not be construed as limiting the position or orientation of a structure or element, but should be used to provide spatial relationship between structures or elements.

For the purposes of this disclosure, the term “lateral” refers to a direction parallel to a plane of the top surface of the microelectronic device. The term “vertical” is understood to refer to a direction perpendicular to the plane of the instant top surface of the microelectronic device.

For the purposes of this disclosure, the term “conductive” is to be interpreted as “electrically conductive”. The term “conductive” refers to materials and structures capable of supporting a steady electrical current, that is, direct current (DC).

For the purposes of this disclosure, unless otherwise noted, the term high stress silicon dioxide refers to a silicon dioxide film with a stress of between −150 megapascal (MPa) and −80 MPa and the term low stress silicon dioxide refers to a silicon dioxide film with a stress of between −60 MPa and −10 MPa. Additionally, by convention, a negative stress implies a compressive stress and a positive stress implies a tensile stress.

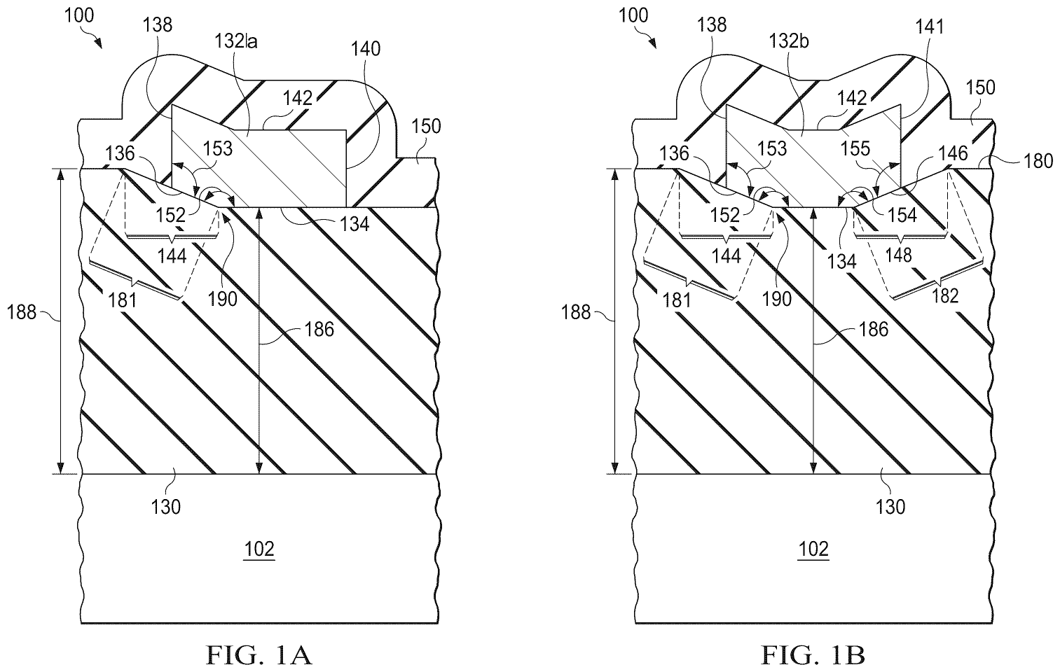

FIG. 1A is a cross section of an example microelectronic device 100 which contains a beveled interconnect 132a. The beveled interconnect 132a is over an interconnect dielectric layer 130, sometimes referred to as a dielectric layer 130. The dielectric layer 130 has a top surface 180. The dielectric layer 130 is over a substrate 102. The dielectric layer 130 may be or include an oxide such as silicon dioxide, a nitride such as silicon nitride, silicon oxynitride, or another dielectric material. The dielectric layer 130 has a beveled interconnect dielectric layer first beveled region 144, sometimes referred to as a first beveled region 144. The first beveled region 144 has a first beveled region top surface 181.

The top surface 180 includes three surface segments: a first surface segment at a first height 186 over the substrate 102, a second surface segment at a second height 188, greater than the first height 186 over the substrate 102, and a third surface segment, e.g. The first beveled region top surface 181, in the first beveled region 144 that connects the first surface and the second surface. The first and third surface segments meet to form a beveled corner with an obtuse angle 152, sometimes referred to as a first beveled interconnect angle 152.

The beveled interconnect 132a has a first bottom surface 134 on or over the first surface segment which is parallel to the substrate 102 surface. The beveled interconnect 132a has a second bottom surface 136 on or over the first beveled region top surface 181 that intersects the first bottom surface 134 with the obtuse angle 152 at a first beveled corner 190. The portion of the beveled interconnect 132a having the first bottom surface 134 may be referred to as a first interconnect segment of the beveled interconnect 132a, and the portion of the beveled interconnect 132a having the second bottom surface 136 may be referred to as a second interconnect segment of the beveled interconnect 132a. The second bottom surface 136 is over the first beveled region 144 and ends over the first beveled region 144. In the illustrated example a first sidewall 138 is located over the first beveled top surface 181, a second sidewall 140 is located over the first bottom surface 134, and a top surface 142 extends between the first sidewall 138 and the second sidewall 140. In various examples the first beveled region 144 has a lateral length of about 1 μm. In some examples the first sidewall 138 is about over a midpoint of the first beveled region top surface 181, e.g. About 500 nm from the first surface segment and about 500 nm from the second surface segment.

The second bottom surface 136 and the first beveled region top surface 181, being coplanar, both form a corner with the first sidewall 138 with a sidewall angle 153. During operation the corner may result in a locally high electric field that can lead to immediate dielectric breakdown or reduced lifetime of the microelectronic device 100. The first beveled region 144 causes the sidewall angle 153 to be greater than 90° (obtuse), thus reducing the electric field at the corner as compared to the alternative in which the corner angle is close to 90°. In some process technologies the angle of the first sidewall 138 with respect to the first and second surface segments, or the first bottom surface 134, is typically close to but not less than 90°, and may vary by as much as ±5° from device to device depending on, e.g. Die location on a handle wafer. As discussed further below, the inventors have discovered that a value of the sidewall angle 153 greater than 100°, e.g. 104° or more, results in a reduction of the electric field at the corner during operation of at least about 15% in some configurations, which is expected to significantly increase the operating lifetime of devices consistent with the microelectronic device 100 and/or increase the maximum operating voltage that results in a particular lifetime specification.

A protective overcoat 150 may be over the beveled interconnect 132a. The protective overcoat 150 may be a single layer of a dielectric such as silicon nitride or silicon oxynitride, or may include multiple dielectric layers. The protective overcoat 150 may provide a portion of a hermetic seal for the microelectronic device 100.

FIG. 1B is a cross section of an example microelectronic device 100 that contains a beveled interconnect 132b that is beveled on two opposite sides. Like reference numbers in FIG. 1B refer to like features in FIG. 1A and may be described similarly. In this view the top surface 180 includes two additional surface segments: a fourth surface segment at the second height 188 over the substrate 102, and a fifth surface segment, e.g. A second beveled region top surface 182 in a second beveled region 148, that connects the first surface segment and the fourth surface segment. The first and fourth surface segments meet to form a second beveled corner with an obtuse angle 154, sometimes referred to as a second beveled interconnect angle 154. Thus the beveled interconnect 132b includes two beveled segments, the first as described with respect to FIG. 1A, and a second beveled segment that extends over the second beveled region 148 and the second beveled region top surface 182.

The beveled interconnect 132b also has a third bottom surface 146 on or over the second beveled region top surface 182, the third bottom surface 146 being non-parallel to the substrate 102 and intersecting the first bottom surface 134 at the second beveled interconnect angle 154 at a first beveled corner 190. A second sidewall 141 of the beveled interconnect 132b is located over the second beveled region top surface 182 in the illustrate example, but in other examples may extend over the top surface 180. The second sidewall 141 and the third bottom surface 146 form a second corner with a sidewall angle 155. As for first corner with the sidewall angle 153, the first beveled region 144 causes the sidewall angle 155 to be obtuse, thus reducing the electric field at the second corner as well as the first corner and providing similar benefit.

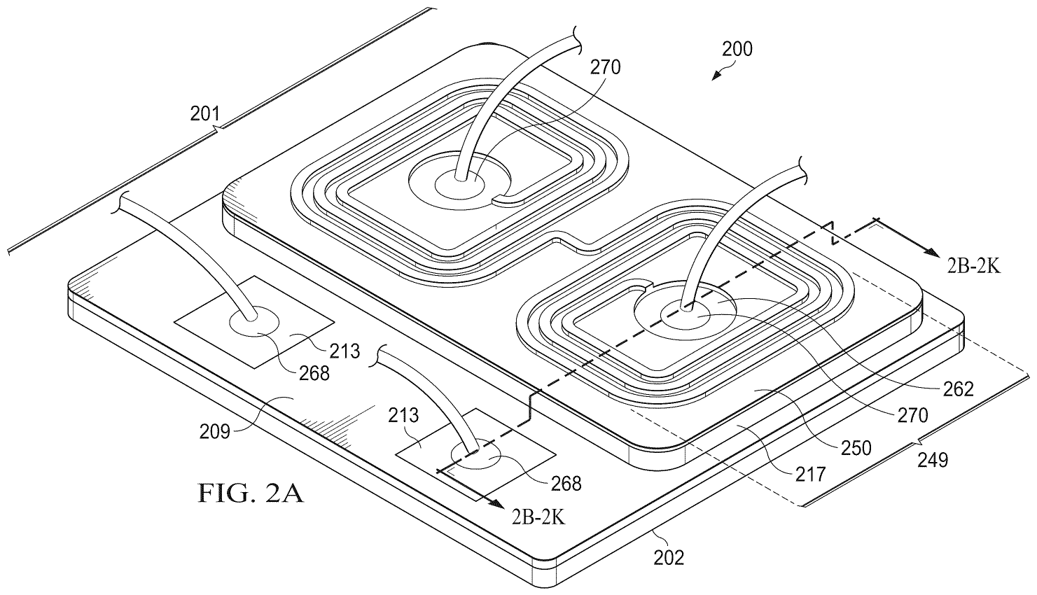

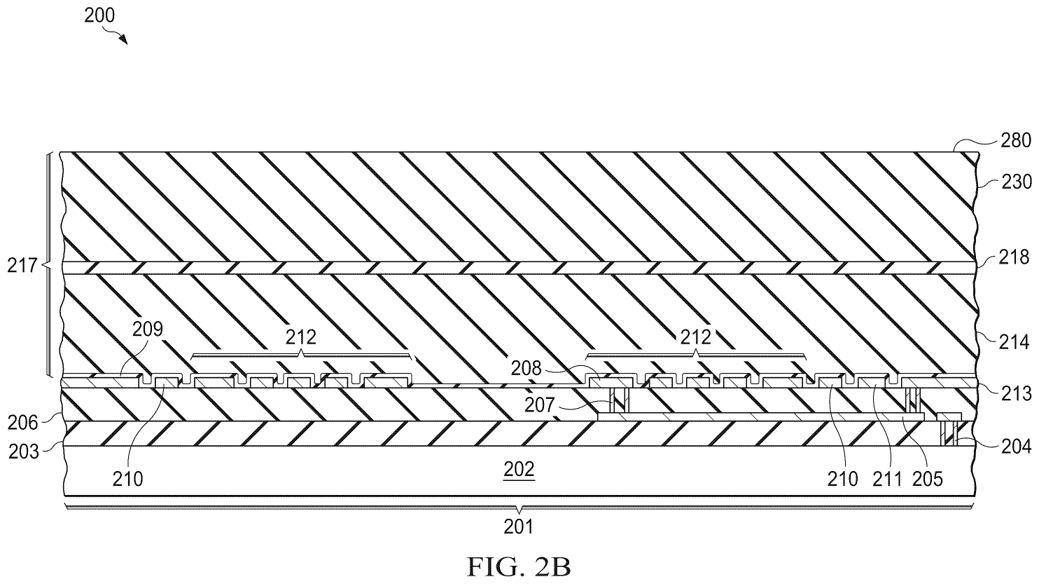

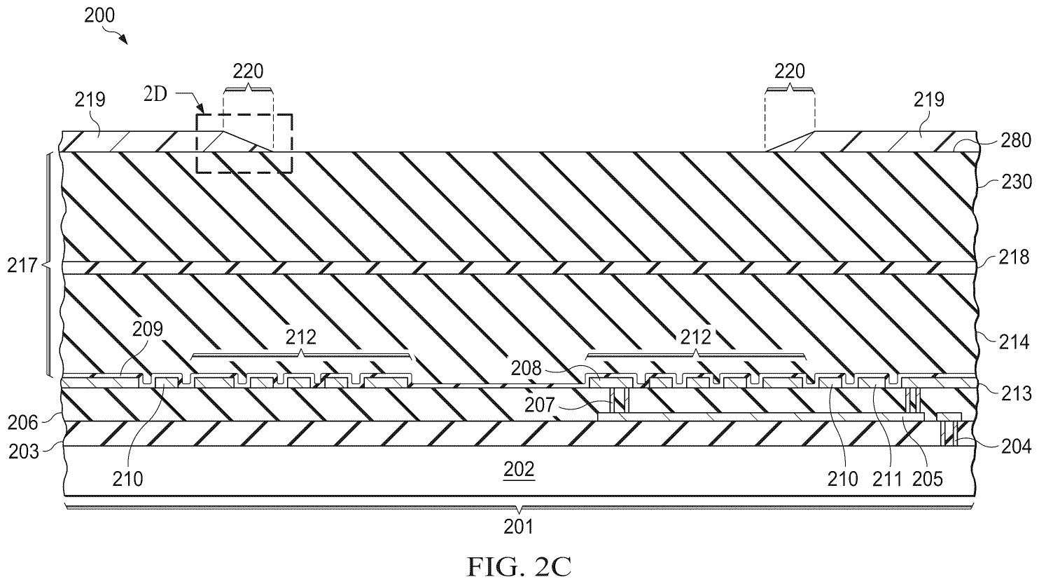

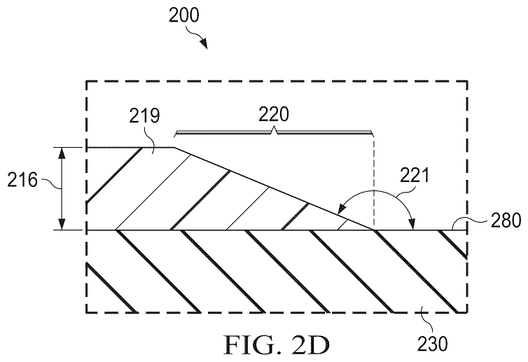

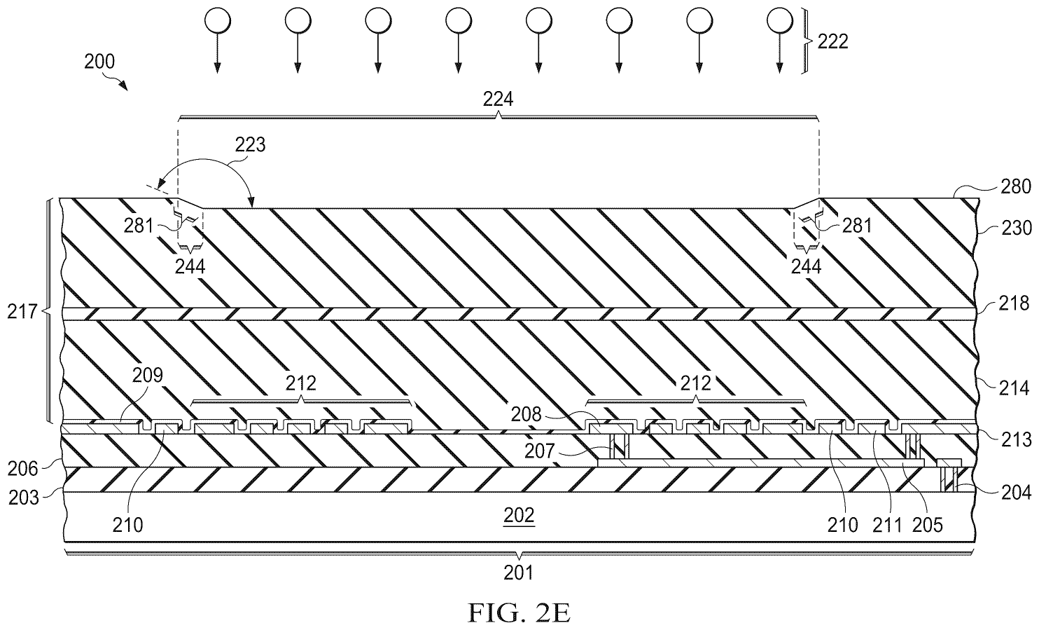

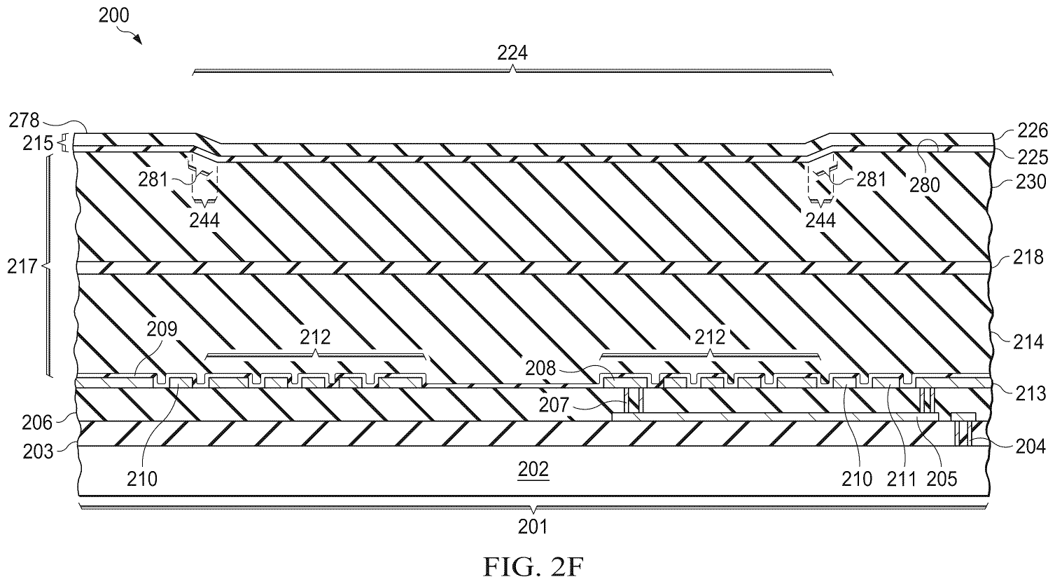

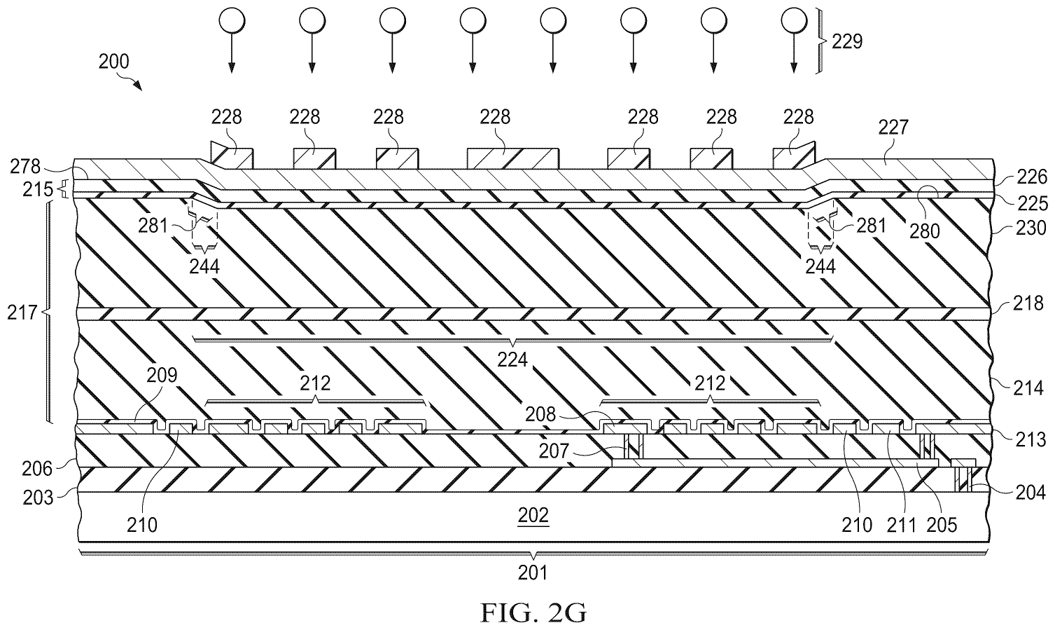

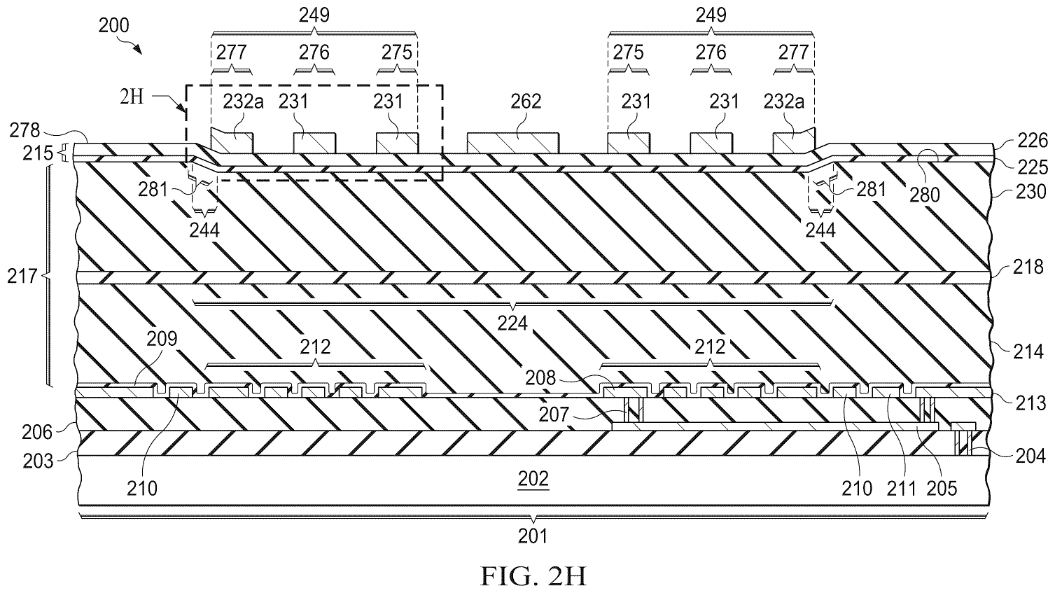

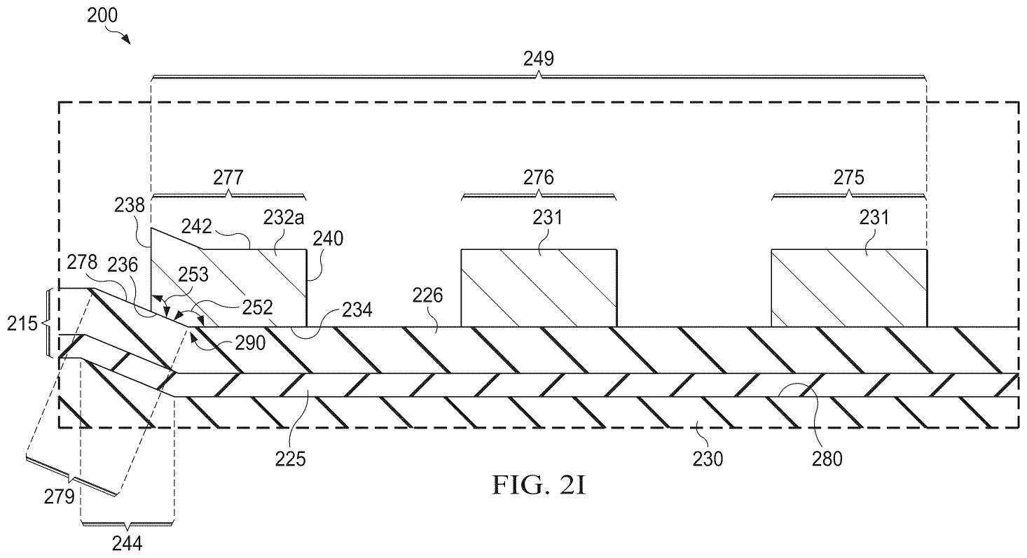

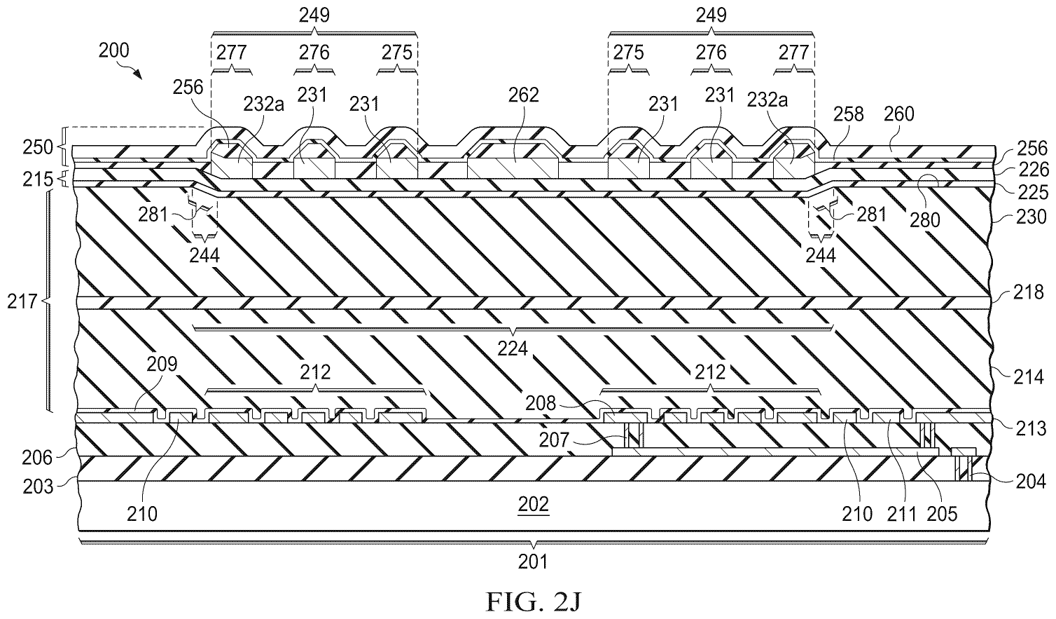

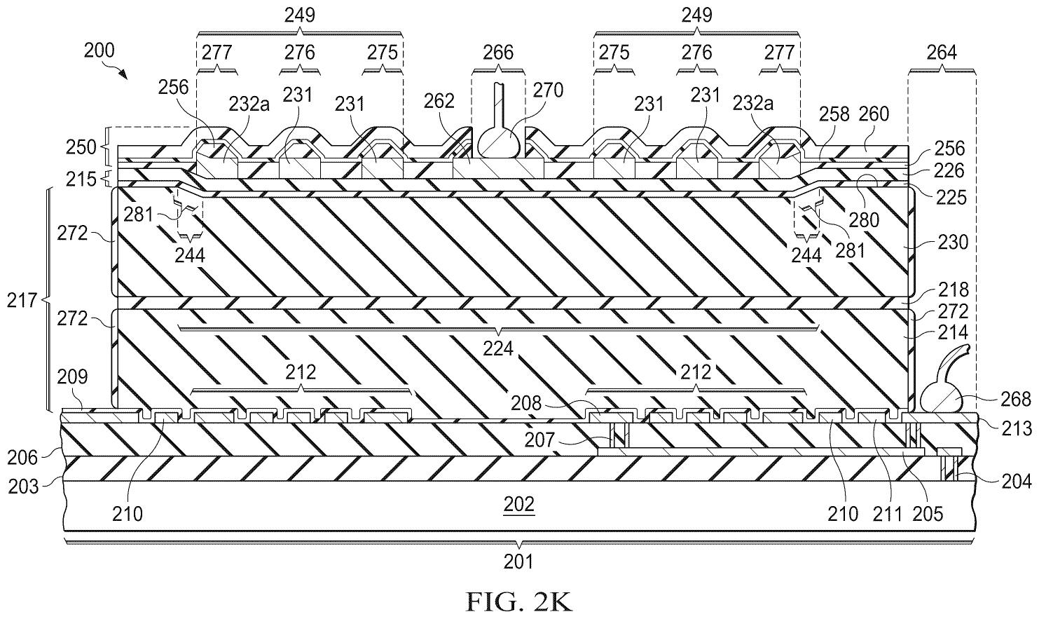

FIG. 2A show a perspective view of a microelectronic device 200 with an isolation device 201 after formation, (formation steps referred to in FIG. 2B-FIG. 2K). While the perspective view in FIG. 2A does not specifically show the beveled interconnect 132a (referred to in FIG. 1A), the perspective view shown in FIG. 2A is included to demonstrate the coiled structure of an upper isolation element 249, sometimes referred to as an upper metal coil 249, which is referred to in cross sectional views in FIG. 2B-FIG. 2K. Other elements shown in the perspective view include the substrate 202, a lower bond pad region 213, a lower ball bond 268, a dielectric stack 217, an upper metal bond pad 262, an upper ball bond 270, and a protective overcoat 250.

FIG. 2B is a cross section of an example microelectronic device 200 including a portion of an isolation device 201 after the formation of a dielectric stack 217. The microelectronic device 200 may be implemented as part of a multi-chip array to provide galvanic isolation between a high voltage component and a low voltage component. The isolation device 201 of this example is a transformer, but could include a capacitor, a magnetic isolator, an optical isolator, a thermal isolator an inductive isolator, or other elements which require galvanic isolation between high voltage and low voltage elements. The microelectronic device 200 is formed on a substrate 202, which may be part of a semiconductor wafer and may contain additional microelectronic devices. The substrate 202 includes a semiconductor material. The semiconductor material may include crystalline silicon, or may include another semiconductor material, such as silicon germanium, silicon carbide, gallium nitride, or gallium arsenide, by way of example.

A pre-metal dielectric (PMD) layer 203 is formed over the substrate 202. The PMD layer 203 includes one or more dielectric layers of silicon dioxide, phosphosilicate glass (PSG), fluorosilicate glass (FSG), borophosphosilicate glass (BPSG), organosilicate glass (OSG), low-k dielectric material, silicon nitride, silicon oxynitride, silicon carbide, silicon carbide nitride, or other dielectric materials. The PMD layer 203 may be formed by one or more dielectric deposition processes, such as a low-pressure chemical vapor deposition (LPCVD) process, a plasma enhanced chemical vapor deposition (PECVD) process, a high aspect ratio process (HARP) using ozone and tetraethyl orthosilicate (TEOS), high density plasma deposition (HDP), or an atmospheric pressure chemical vapor deposition (APCVD) process.

Contacts 204 to the first level interconnects 205 are formed through the PMD layer 203 to make electrical connections to the substrate 202. The contacts 204 are electrically conductive, and may include tungsten on a titanium adhesion layer and a titanium nitride liner. The contacts 204 may be formed by etching contact holes through the PMD layer 203, and forming the titanium adhesion layer by a physical vapor deposition (PVD) process. A titanium nitride liner may be formed on the titanium adhesion layer by a physical vapor deposition (PLD) process or chemical vapor deposition (CVD) process. The tungsten may be formed on the titanium nitride liner by a plasma enhanced chemical vapor deposition (MOCVD) process using tungsten hexafluoride reduced by silane and hydrogen. Tungsten, titanium nitride, and titanium on a top surface of the PMD layer 203, outside of the contacts 204, may be removed by a tungsten etch back process, a tungsten chemical mechanical polish (CMP) process, or both.

By way of example, the metallization of the isolation device 201 is described for an etched aluminum-based interconnect system. The isolation device 201 may also be formed using a copper-based interconnect system. First level interconnects 205 are formed on the PMD layer 203, making electrical connections to the contacts 204. The first level interconnects 205 are electrically conductive. The first level interconnects 205 may have an etched aluminum structure. The first level interconnects 205 may include an adhesion layer, not shown, of titanium nitride or titanium tungsten, on the PMD layer 203, an aluminum layer, with a few atomic percent of silicon, titanium, or copper, on the adhesion layer, and an anti-reflection layer, not specifically shown, of titanium nitride on the aluminum layer. An etch mask, not specifically shown, is formed followed by a reactive ion etch (RIE) process to etch the anti-reflection layer, the aluminum layer, and the adhesion layer where exposed by the etch mask, and subsequently removing the etch mask to form the first level interconnects 205.

A first interlevel dielectric (ILD) layer 206 which may include a single layer of dielectric or multiple dielectric layers may be formed on the first level interconnects 205. After the formation of the first ILD layer 206, first level vias 207 are formed in the first ILD layer 206, making electrical connection to the first level interconnects 205. The first level vias 207 may be formed by etching via holes through the first ILD layer 206, and forming a titanium adhesion layer by a PVD process. A titanium nitride liner may be formed on the titanium adhesion layer by a PVD process or CVD process. Tungsten may be formed on the titanium nitride liner by a metalorganic PECVD process using tungsten hexafluoride reduced by silane and hydrogen. Tungsten, titanium nitride, and titanium on a top surface of the first level vias 207, outside of the via holes, may be removed by a tungsten etch back process, a tungsten CMP process, or both.

Second level interconnects 208 are formed on the first ILD layer 206 making electrical contact with the first level vias 207. The second level interconnects 208 are electrically conductive. The second level interconnects 208 may have an etched aluminum structure. The second level interconnects 208 may include an adhesion layer, not specifically shown, of titanium nitride or titanium tungsten, on the first ILD layer 206, an aluminum layer, with a few atomic percent of silicon, titanium, or copper, on the adhesion layer, and an anti-reflection layer, not specifically shown, of titanium nitride on the aluminum layer. A second interconnects etch mask (not specifically shown), is formed followed by an RIE process to etch the anti-reflection layer, the aluminum layer, and the adhesion layer where exposed by the etch mask, and subsequently removing the etch mask to form the second level interconnects 208. In this example, a lower isolation element 212, sometimes referred to as a lower metal coil 212, of the isolation device 201 may be formed in the second level interconnects 208, but may be formed at other levels. A ground ring 210 (grounding outside of the plane of the cross section of FIG. 2B) for the isolation device 201 is also formed in the second level interconnects 208. Grounded second level interconnects filler metal 211 (grounding outside of the plane of the cross section of FIG. 2B) may also be formed in the second level interconnects 208. The lower bond pad region 213 may also be formed in the second level interconnects 208.

A dielectric stack 217 is deposited on the second level interconnects 208 which provides isolation between the lower metal coil 212 and the upper metal coil 249 (referred to in FIG. 2H). The dielectric layers composing the dielectric stack 217 may singly or in combination be composed of low stress silicon dioxide, high stress silicon dioxide, HDP silicon dioxide, silicon oxynitride, and silicon nitride or other similar dielectric materials. The low stress silicon dioxide may have a stress between −60 MPa and −10 MPa. The high stress silicon dioxide may have a stress between −150 MPa and −80 MPa. The HDP silicon dioxide may have a stress between −120 MPa and −90 MPa. The silicon oxynitride may have a stress between −120 MP and 0 MPa. The silicon nitride may have a stress between −1 GPa and −100 MPa. The dielectric stack may also contain an etch stop layer 209 of silicon nitride or silicon oxynitride over the lower metal coil 212 and the lower bond pad region 213. The dielectric stack may also contain a dielectric stack etch stop layer 218 of silicon nitride or silicon oxynitride within the dielectric stack 217. In the example isolation device 201, the dielectric stack etch stop layer 218 is between a dielectric stack lower dielectric layer 214 and a beveled interconnect dielectric layer 230. The beveled interconnect dielectric layer 230 has a beveled interconnect dielectric top surface 280.

Referring to FIG. 2C, a cross section is shown after a beveled interconnect dielectric recess resist pattern 219, sometimes referred to as a resist pattern 219 is formed. A greyscale photo mask (not specifically shown) is used to create a resist pattern beveled region 220 at the edges of the resist pattern 219. An inset of the resist pattern beveled region 220 is shown in FIG. 2D. Aspects of greyscale lithography are described in U.S. Pat. No. 11,205,695, incorporated herein by reference in its entirety.

FIG. 2D is an inset of FIG. 2C in the resist pattern beveled region 220 near the edge of the resist pattern 219. The resist pattern beveled region 220 is a region where the resist transitions from a full resist height 216 with a resist pattern bevel angle 221.

Referring to FIG. 2E, a cross section is shown after a beveled interconnect dielectric etch 222 and a resist clean up step (not specifically shown) have formed a beveled interconnect dielectric recess region 224 with a beveled interconnect dielectric top surface 280. Due to the resist pattern beveled region 220 at the edges of the resist pattern 219 (FIG. 2C-FIG. 2D), the beveled interconnect dielectric etch 222 may form the beveled interconnect dielectric recess region 224 which may include a beveled interconnect dielectric layer first beveled region 244, sometimes referred to as a first beveled region 244, at the edges of the beveled interconnect dielectric recess region 224. The first beveled region 244 has a first beveled region top surface 281. While a greyscale photomask may be used to form the first beveled region 244, other means of generating a beveled etch profile at the edges of the beveled interconnect dielectric recess region 224 are within the scope of the disclosure.

After the beveled interconnect dielectric etch 222 and clean up, a wet etch based on HF chemistry may be used to optimize the profile of the first beveled region 244 at the corners of the first beveled region 244. Depending on the beveled interconnect dielectric etch 222 process used to form the beveled interconnect dielectric recess region 224, the resist pattern bevel angle 221 may or may not translate in a one-to-one relationship to the angle of the beveled interconnect dielectric angle 223 formed after the beveled interconnect dielectric etch 222, e.g., The beveled interconnect dielectric angle 223 may be steeper or shallower than the resist pattern bevel angle 221.

Referring to FIG. 2F, a beveled interconnect dielectric cap layer 215 having a top surface 278 (referred to in FIG. 2I) is formed on the beveled interconnect dielectric layer 230. The beveled interconnect dielectric cap layer 215 is a dielectric layer and may be a single layer of a silicon nitride, silicon oxynitride, silicon dioxide or be multiple layers including a combination of silicon nitride, silicon oxynitride and silicon dioxide dielectric materials. In the example device shown in FIG. 2F, the beveled interconnect dielectric cap layer 215 is a bilayer, with a first beveled dielectric cap layer 225 of silicon oxynitride on the beveled interconnect dielectric layer 230. The first beveled dielectric cap layer 225 may be formed by a PECVD process using a combination of BTBAS and TEOS, or a combination of dichlorosilane and nitrous oxide, for example. The first beveled dielectric cap layer 225 may have a thickness between 100 nm and 400 nm, and a stress between −120 MPa and 0 MPa. Following the formation of the first beveled dielectric cap layer 225, a second beveled dielectric cap layer 226 is formed on the first beveled dielectric cap layer 225. The second beveled dielectric cap layer 226 may be silicon nitride and may be deposited by a CVD or PECVD process and is 200 nm to 1200 nm in thickness with a stress between −1 GPa and −100 MPA.

Referring to FIG. 2G a beveled interconnect metal layer 227 is formed on the beveled interconnect dielectric cap layer 215. The beveled interconnect metal layer 227 may have an etched aluminum structure, and may include an adhesion layer, not specifically shown, of titanium nitride or titanium tungsten, upper, an aluminum layer, not specifically shown, with a few atomic percent of silicon, titanium, or copper, on the adhesion layer, and an anti-reflection layer, not specifically shown, of titanium nitride on the aluminum layer. A beveled interconnects photolithography mask 228 is formed followed by an RIE process 229 to etch the anti-reflection layer, the aluminum layer, and the adhesion layer where exposed by the etch mask. The RIE used to etch the beveled interconnect metal layer 227 may remove up to 200 nm of the beveled interconnect dielectric cap layer 215 in areas exposed to the RIE process 229. The RIE process 229 is followed by removal of the beveled interconnects photolithography mask 228 and a cleanup step (neither specifically shown). The beveled interconnect metal layer 227 features after the RIE process 229 are referred to in FIG. 2H

Referring to FIG. 2H, a cross section of the isolation device 201 after the RIE process 229 referred to in FIG. 2G. Any removal of the second beveled dielectric cap layer 226 from the RIE process 229 referred to in FIG. 2G is not shown for clarity. The RIE process 229 defines a first bond pad 262, sometimes referred to as an upper metal bond pad 262. The RIE process 229 also defines the upper metal coil 249.

In the example isolation device 201 the upper metal bond pad 262 is near the center of the upper metal coil 249. The upper metal coil 249 comprises an inner turn 275 nearest the upper metal bond pad 262, an outer turn 277 farthest away from the upper metal bond pad 262, and a middle turn 276 between the inner turn 275 and the outer turn 277. While the upper metal coil 249 of the example isolation device 201 comprises three turns, an upper metal coil 249 with more turns or fewer turns is within the scope of the disclosure.

A portion of the beveled interconnect 232a of the outer turn 277 is over the first beveled region 244. The middle turn 276 and inner turn 275 are comprised of non-beveled interconnects 231. In the cross section of FIG. 2H, the outer turn 277 is a continuous conductor feature, and may be over a first beveled region 244 which is continuous under the outer turn 277 with a beveled interconnect 232a which is continuous around the outer turn 277. The outer turn 277 may also be over more than one first beveled region 244 which may be discontinuous under the outer turn 277 which results in an outer turn 277 which may contain some regions with a beveled interconnect 232a, and contain some regions and with a non-beveled interconnect 231 (not specifically shown).

Referring to FIG. 2I, an inset of FIG. 2H is shown. The upper metal coil 249 is over the beveled interconnect dielectric cap layer 215, the beveled interconnect dielectric cap layer 215, being on the beveled interconnect dielectric layer 230.

A portion of the beveled interconnect 232a on the outer turn 277 is over the first beveled region 244. When a beveled interconnect dielectric cap layer 215 is between the beveled interconnect 232a and the beveled interconnect dielectric layer 230, the deposition characteristics of the beveled interconnect dielectric cap layer 215 may shift the location of the dielectric cap bevel region 279 at the top surface 278 of the beveled interconnect dielectric cap layer 215 such as it may not be directly over the first beveled region 244. The first beveled region 244 has a width which accounts for process variation such that the first sidewall 238 is over the dielectric cap bevel region 279 which allows formation of a beveled interconnect 232a when the beveled interconnect dielectric cap layer 215 is present. The first beveled region 244 has a width which accounts for process variation such that the first sidewall 238 is over the first beveled region 244 which allows formation of a beveled interconnect 232a when a beveled interconnect dielectric cap layer 215 is not present.

The beveled interconnect 232a has a first bottom surface 234 over the beveled interconnect dielectric layer 230 and a second bottom surface 236 contacting the first bottom surface 234 with a first beveled interconnect angle 252 at a first beveled corner 290. The first beveled interconnect angle 252 is greater than ninety degrees. The second bottom surface 236 may be over the first beveled region 244 or over the dielectric cap bevel region 279 if present. Other features of the beveled interconnect 232a include a first sidewall 238 contacting the second bottom surface 236, a second sidewall 240 contacting the first bottom surface 234, and a top surface 242 over a portion of the first bottom surface 234. The first sidewall 238 and the second bottom surface 236 form a sidewall angle 253 that may confer similar benefit as described with respect to the sidewall angle 153.

It may be advantageous for the upper metal coil 249 to include a beveled interconnect 232a including a second bottom surface 236, e.g., The bevel of the beveled interconnect 232a, which is farther from the upper metal bond pad 262 referred to in FIG. 2H than the second sidewall 240 as the region near the second bottom surface 236 is a region of high electric field during the operation of the isolation device 201. A beveled interconnect 232a at this location may reduce the maximum electric field of the upper metal coil 249 compared to an upper metal coil 249 formed solely of traditional interconnects similar in profile to the non-beveled interconnect 231. The inner turn 275 and the middle turn 276 of the upper metal coil 249 consists of non-beveled interconnects 231.

FIG. 2J is a cross section of the microelectronic device 200 after a protective overcoat 250 is formed over the upper metal coil 249. The protective overcoat 250 may be a single layer, or may be of more than one layer as shown in FIG. 2J. The protective overcoat shown in FIG. 2J may be formed by a deposition of silicon oxynitride, silicon nitride, or a combination thereof. The protective overcoat 250 may include a PO silicon dioxide layer 256 (HDP oxide in this example) formed over the beveled interconnect dielectric cap layer 215 and the upper metal coil 249. A PO silicon nitride 258 may be on the PO silicon dioxide layer 256, and a PO silicon oxynitride 260 may be on the PO silicon nitride 258.

FIG. 2K is a cross section of the microelectronic device 200 after a series of etch steps (not specifically shown) have removed the protective overcoat 250 in the upper bond pad region 266 to expose the upper metal bond pad 262 as well as the removing the protective overcoat and the dielectric stack in the lower bond pad region 264 to expose the lower bond pad region 213. The etching of the dielectric stack 217 may result in a vertical dielectric sidewall. The etch stop layer 209, may remain in areas outside the lower bond pad region 213. The dielectric stack lower dielectric layer 214 and the beveled interconnect dielectric layer 230 are oxide materials and subject to moisture ingress through a dielectric stack sidewall dielectric 272 that may cause dielectric cracking during operation of the example isolation device 201. A plasma treatment with a nitrogen containing reagent such as ammonia may be used to form the dielectric stack sidewall dielectric 272 on the etched vertical surfaces of the isolation device 201 to prevent moisture ingress into the dielectric stack 217. The dielectric stack sidewall dielectric may be from 1 nm to greater than 10 nm based on the plasma treatment formation conditions. The plasma treatment is a surface treatment which reacts with the silicon dioxide of the dielectric stack sidewall dielectric 272 and is not a CVD deposition. The stoichiometry of dielectric stack sidewall dielectric 272 is most nitrogen rich with a stoichiometry of SiOₓN_{y} at the surface of the dielectric stack sidewall dielectric 272 with the nitrogen concentration becoming lower farther from the surface of the dielectric stack sidewall dielectric 272.

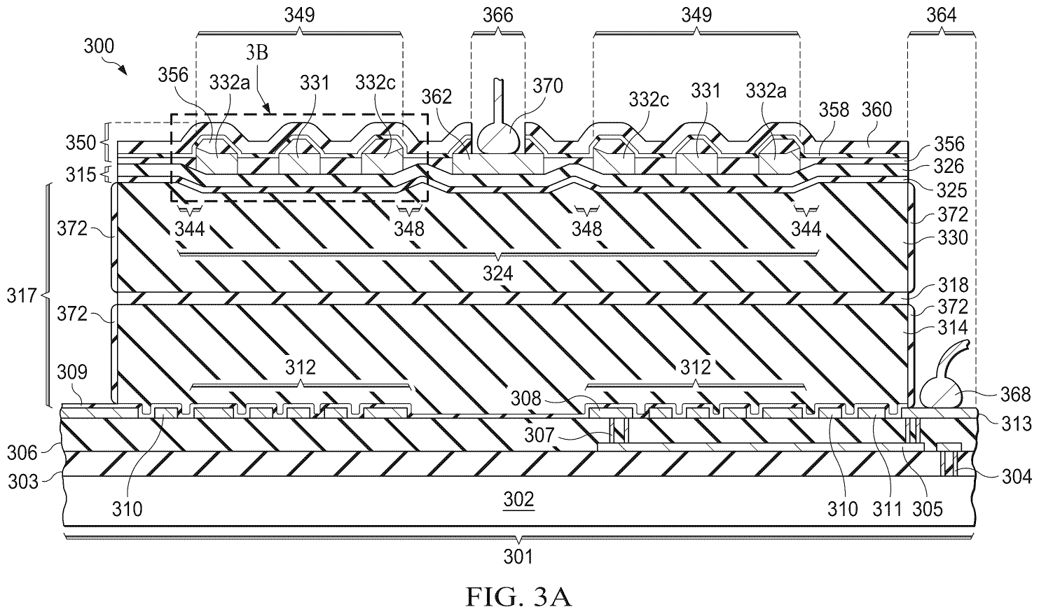

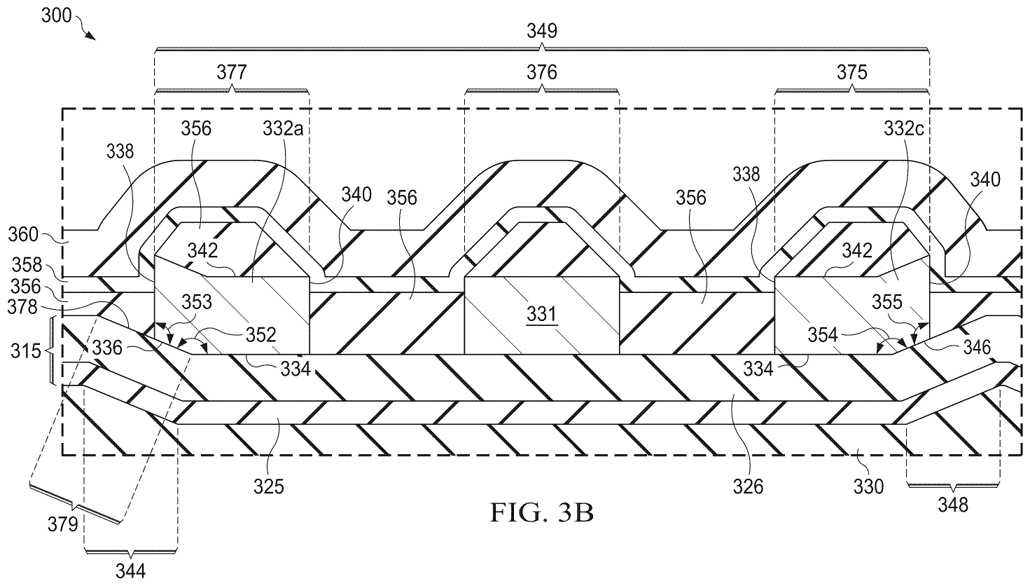

Referring to FIG. 3A, a cross section of a microelectronic device 300 including an isolation device 301 is shown. The isolation device 301 is formed using a process similar to that shown in FIG. 2B-FIG. 2K. Unlike the microelectronic device shown in FIG. 2K in which only the outer turn 377 of an upper isolation element 349, sometimes referred to as an upper metal coil 349, contains a beveled interconnect 332a, the isolation device 301 has a beveled interconnect 332a on the outer turn 377 of the upper metal coil 349 and a beveled interconnect 332c on the inner turn 375 of the upper metal coil 349.

To form a beveled interconnect 332c on both the inner turn 375 and a beveled interconnect 332a the outer turn 377 of the upper metal coil 349, the recess resist pattern 219 (FIG. 2C) is modified to form a beveled interconnect dielectric recess region 324 with a beveled dielectric stack recess first beveled region 344, sometimes referred to as a first beveled region 344, under a portion of the outer turn 377 farthest from the bond pad 362, and a beveled dielectric stack recess second beveled region 348, sometimes referred to as a second beveled region 348, under a portion of the inner turn 375 nearest the bond pad 362. A beveled interconnect 332c with a bevel on the inner turn 375 nearest the bond pad 362 and a beveled interconnect 332a on the outer turn 377 farthest away from the bond pad 362 may reduce the maximum electric fields of the isolation device 301 when the isolation device 301 is in operation, thus providing enhanced protection against dielectric breakdown of the dielectric stack 317, or may enable the isolation device 301 to function with a higher potential difference between the upper metal coil 349 and a lower isolation element 312 sometimes referred to as a lower metal coil 312. Other components of FIG. 3A include a substrate 302, a pre-metal dielectric 303, contacts 304, first level interconnects 305, a first inter level dielectric 306, first level vias 307, second level interconnects 308, a second level interconnects etch stop layer 309, a ground ring 310, grounded second level interconnects filler metal 311, a second bond pad 313, sometimes referred to as a lower metal coil bond pad 313, a lower dielectric layer of the dielectric stack 314, a dielectric stack 317, a dielectric stack etch stop layer 318, a first beveled dielectric cap layer 325, a second beveled dielectric cap layer 326, a beveled interconnect dielectric layer 330, a non-beveled interconnect 331, a lower bond pad region 364, an upper bond pad region 366, a lower ball bond 368, an upper ball bond 370, a dielectric stack sidewall dielectric 372, a middle turn 376, a protective overcoat 350, a PO silicon dioxide 356, a PO silicon nitride 358, and a PO silicon oxynitride 360.

Referring to FIG. 3B, an inset of FIG. 3A is shown. The upper metal coil 349 is over the beveled interconnect dielectric cap layer 315, with the beveled interconnect dielectric cap layer 315, being on the beveled interconnect dielectric layer 330.

A portion of the beveled interconnect 332a on the outer turn 377 is over the first beveled region 344. When a beveled interconnect dielectric cap layer 315 is between the beveled interconnect 332a and the beveled interconnect dielectric layer 330, the deposition characteristics of the beveled interconnect dielectric cap layer 315 may shift the location of the dielectric cap bevel region 379 at the top surface 378 of the beveled interconnect dielectric cap layer 315 such as it may not be directly over the first beveled region 344. The first beveled region 344 has a width which accounts for process variation such that the first sidewall 338 is over the dielectric cap bevel region 379 which allows formation of a beveled interconnect 332a when a beveled interconnect dielectric cap layer 315 is present. The first beveled region 344 has a width which accounts for process variation such that the first sidewall 338 is over the first beveled region 244 which allows formation of a beveled interconnect 332a when a beveled interconnect dielectric cap layer 315 is not present.

The beveled interconnect 332a over the first beveled region 344 has a first bottom surface 334 over the beveled interconnect dielectric layer 330 and a second bottom surface 336 contacting the first bottom surface 334 with a first beveled interconnect angle 352. The first beveled interconnect angle 352 is greater than ninety degrees. The second bottom surface 336 may be over the first beveled region 344 or the dielectric cap bevel region 379 if present. Other features of the beveled interconnect 332a over the first beveled region 344 include a first sidewall 338 contacting the second bottom surface 336, a second sidewall 340 contacting the third bottom surface 346, and a top surface 342 over a portion of the first bottom surface 334.

A portion of the beveled interconnect 332c on the inner turn 375 is over the second beveled region 348. The beveled interconnect 332c over the second beveled region 348 has a first bottom surface 334 over the beveled interconnect dielectric layer 330 and a third bottom surface 346 contacting the first bottom surface 334 with a second beveled interconnect angle 354. The second beveled interconnect angle 354 is greater than ninety degrees, and is the same as the beveled interconnect dielectric angle 223 (referred to in FIG. 2E) within the variation induced by processing. Other features of the beveled interconnect 332c over the second beveled region 348 include a second sidewall 340 contacting the third bottom surface 346, a first sidewall 338 contacting the first bottom surface 334, and a top surface 342 over a portion of the first bottom surface 334. The first sidewall 338 and the second bottom surface 336 form a sidewall angle 353, and the second sidewall 340 and the third bottom surface 346 form a sidewall angle 355. The sidewall angles 353 and 355 may confer similar benefit as described with respect to the sidewall angle 153.

It may be advantageous for the upper metal coil 349 to include a beveled interconnect 332a on the outer turn 377 with a first sidewall 338 over the first beveled region 344 and another beveled interconnect 332c on the inner turn 375 with a second sidewall 340 over the second beveled region 348 as these are regions of high electric field during the operation of the isolation device 301 may lower the maximum electric field of the upper metal coil 349. The middle turn 376 of the upper metal coil 349 consists of non-beveled interconnect 331.

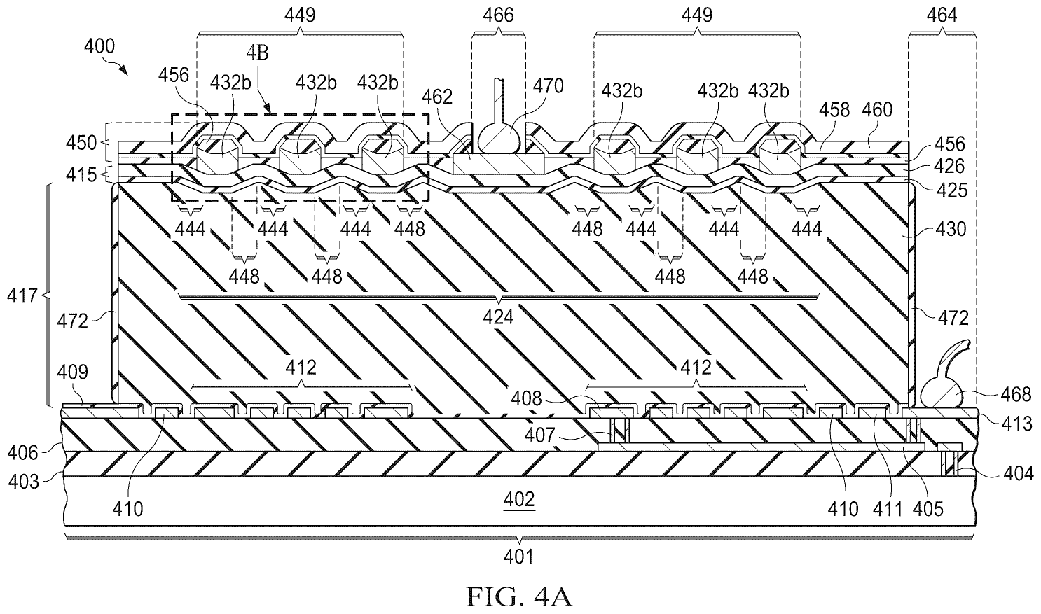

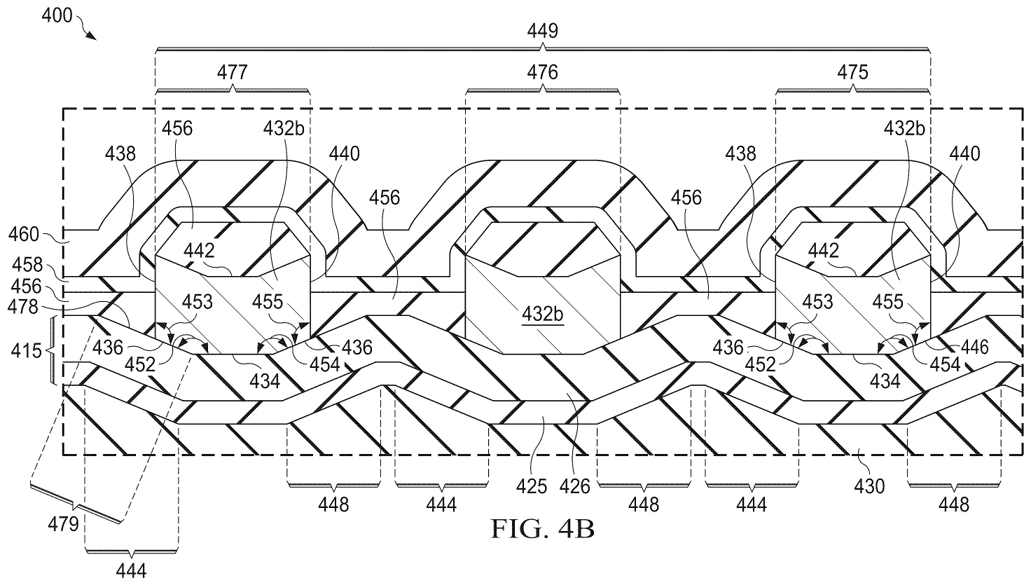

Referring to FIG. 4A, a cross section of a microelectronic device 400 including an isolation device 401 is shown. The isolation device 401 is formed using a process similar to that shown in FIG. 2B-FIG. 2K. Unlike the microelectronic device shown in FIG. 2K in which only the outer turn 477 of the upper metal coil 449 contains a beveled interconnect 432b, the upper metal coil 449 of FIG. 4A has a beveled interconnect 432b on the outer turn 477, the middle turn 476, and the inner turn 475 of the upper metal coil 449. To form a beveled interconnects 432b in each of the turns of the upper metal coil 449, the resist pattern 219 (FIG. 2C) is modified to form a beveled interconnect dielectric recess region 424 with a beveled interconnect dielectric first beveled region 444, sometimes referred to as a first beveled region 444, under a second bottom surface 436 (referred to in FIG. 4B) and a beveled interconnect dielectric second beveled region 448, sometimes referred to as a second beveled region 448, under a third bottom surface 446 (referred to in FIG. 4B) for each beveled interconnect 432b resulting in a two beveled regions on each of the turns of the top metal coil.

An upper metal coil 449 with a beveled interconnect 432b on all of the turns of the upper metal coil 449 may reduce the maximum electric fields of the isolation device 401 and provide enhanced protection against dielectric breakdown of the dielectric stack 417 or may enable the isolation device 401 to function with a higher potential difference between the upper metal coil 449 and the lower metal coil 412. Other components of FIG. 4A include a substrate 402, a pre-metal dielectric 403, contacts 404, first level interconnects 405, a first inter level dielectric 406, first level vias 407, second level interconnects 408, a second level interconnects etch stop layer 409, a ground ring 410, grounded second level interconnects filler metal 411, a lower isolation element 412, sometimes referred to as a lower metal coil 412, a second bond pad 413, sometimes referred to as a lower metal coil bond pad 413, a dielectric stack 417, a first beveled dielectric cap layer 425, a second beveled dielectric cap layer 426, a beveled interconnect dielectric layer 430, a middle turn 476 of the upper metal coil 449, a protective overcoat 450, a PO silicon dioxide 456, a PO silicon nitride 458, a PO silicon oxynitride 460, an upper metal bond pad 462, a lower bond pad region 464, an upper bond pad region 466, a lower ball bond 468, an upper ball bond 470, and a dielectric stack sidewall dielectric 472

Referring to FIG. 4B, an inset of FIG. 4A is shown. The upper metal coil 449 is over the beveled interconnect dielectric cap layer 415, the beveled interconnect dielectric cap layer 415, being on the beveled interconnect dielectric layer 430.

A portion of the beveled interconnect 432b of each turn of the upper metal coil 449 is over a first beveled region 444 while another portion of the beveled interconnect 432b of each turn is over the second beveled region 448. When a beveled interconnect dielectric cap layer 415 is between the beveled interconnect 432b and the beveled interconnect dielectric layer 430, the deposition characteristics of the beveled interconnect dielectric cap layer 415 may shift the location of a dielectric cap beveled region 479 at the top surface 478 of the beveled interconnect dielectric cap layer 415, such as it may not be directly over the first beveled region 444 or the second beveled region 448. The first beveled region 444 and the second beveled region 448 must both be wide enough to account for such shifting due to the beveled interconnect dielectric cap layer 415 and for photo misalignment of the process such that the first sidewall 438 and the second sidewall 440 are always over the dielectric cap beveled region 479 at the top surface 478 of the beveled interconnect dielectric cap layer 415 when present, or over the first beveled region 444 and the second beveled region 448 of the beveled interconnect dielectric layer 430 when a beveled interconnect dielectric cap layer 415 is not present.

The beveled interconnects 432b of each of the turns of the upper metal coil 449 are over the first beveled region 444 and the second beveled region 448 and includes a first bottom surface 434 over the beveled interconnect dielectric layer 430, a second bottom surface 436 contacting the first bottom surface 434 with a first beveled interconnect angle 452. The first beveled interconnect angle 452 is greater than ninety degrees. The second bottom surface 436 may be over the first beveled region 444 or the dielectric cap beveled region 479 if present. The beveled interconnect 432b also includes a third bottom surface 446 over the second beveled region 448 or the dielectric cap beveled region 479 if present which contacts the first bottom surface 434 with a second beveled interconnect angle 454 of greater than ninety degrees. Other elements of the beveled interconnect 432b include a first sidewall 438 contacting the second bottom surface 436, a second sidewall 440 contacting the third bottom surface 446, and a top surface 442 over a portion of the first bottom surface 434. The first sidewall 438 and the second bottom surface 436 form a sidewall angle 453, and the second sidewall 440 and the third bottom surface 446 form a sidewall angle 455. The sidewall angles 453 and 455 may confer similar benefit as described with respect to the sidewall angle 153.

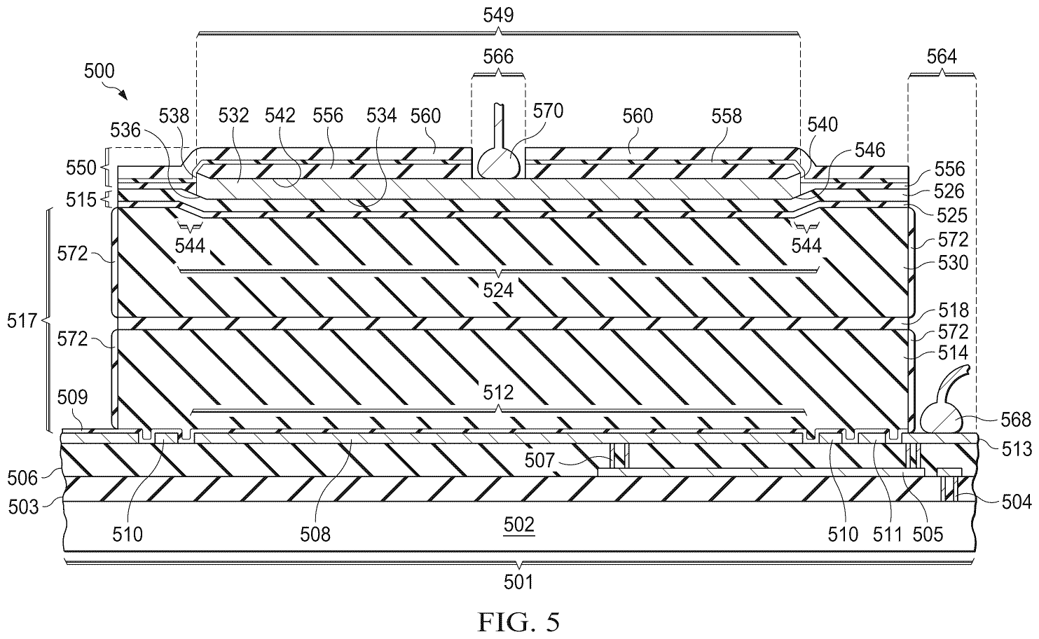

Referring to FIG. 5, a cross section of a microelectronic device 500 including an isolation device 501 is shown. The isolation device 501 is an interconnect based parallel plate capacitor which includes a upper isolation element 549, sometimes referred to as a beveled capacitor top plate 549. The beveled capacitor top plate consists of a beveled interconnect 532. The beveled interconnect 532 has a first bottom surface, 534, with a second bottom surface 536 and a third bottom surface 546 contacting the first bottom surface 534. A top surface 542 of the beveled interconnect 532 is over the first bottom surface 534. A first sidewall 538 contacts the second bottom surface 536 and the top surface 542. A second sidewall 540 contacts the third bottom surface 546 and the top surface 542. The isolation device 501 is formed using a process similar to that shown in FIG. 2B-FIG. 2K. To form the beveled capacitor top plate 549, a beveled interconnect dielectric recess resist pattern (not specifically shown) similar to the resist pattern 219, referred to in FIG. 2C, is used to form a beveled interconnect dielectric recess region 524 with a beveled interconnect dielectric first beveled region 544, sometimes referred to as a first beveled region 544. The first beveled region 544 is continuous around the beveled interconnect dielectric recess region 524. The first beveled region 544 induces a bevel around the bottom perimeter of the beveled capacitor top plate 549. The beveled capacitor top plate 549 consisting of a beveled interconnect 532 may provide reduce the maximum electric fields of the isolation device 501 when the isolation device 501 is in operation as the first beveled region 544 and may provide enhanced protection against dielectric breakdown of the dielectric stack 517 or may enable the isolation device 501 to function with a higher potential difference between the beveled capacitor top plate 549 and the lower isolation element 512, sometimes referred to as the bottom capacitor plate 512.

Other components of FIG. 5 include a substrate 502, a pre-metal dielectric 503, contacts 504, first level interconnects 505, a first inter level dielectric 506, first level vias 507, second level interconnects 508, a second level interconnects etch stop layer 509, a ground ring 510, Grounded second level interconnects filler metal 511, a second bond pad 513, sometimes referred to as a lower metal coil bond pad 513, a lower dielectric layer of the dielectric stack 514, beveled interconnect dielectric cap layer 515, dielectric stack 517, a dielectric stack etch stop layer 518, a first beveled dielectric cap layer 525, a second beveled dielectric cap layer 526, a beveled interconnect dielectric layer 530, a lower bond pad region 564, an upper bond pad region 566, a lower ball bond 568, an upper ball bond 570, a dielectric stack sidewall dielectric 572, a protective overcoat 550, a PO silicon dioxide 556, a PO silicon nitride 558, and a PO silicon oxynitride 560.

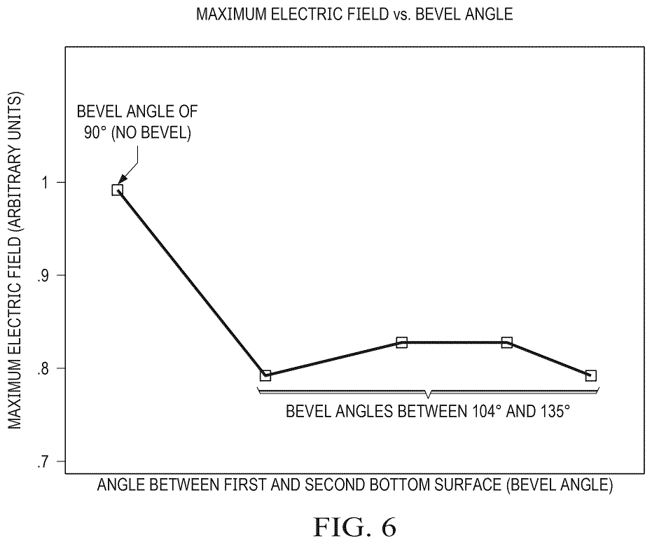

Referring to FIG. 6, a graph is showing a reduction in computed maximum electric field at the corner formed by two segments of a beveled interconnect such as the beveled interconnect 132a (FIG. 1A) for values of the angle formed therebetween (e.g. The first beveled interconnect angle 152) from 90° (right angle) to 140 °. The electric field strength is seen expected to positively correlate with breakdown voltage (BV) and/or reliability of a manufactured device. As shown in the graph, the highest electric field occurs for the case that the corner angle is ninety degrees. At greater than 90°, e.g. 104° and above, the maximum electric field decreases by approximately sixteen to twenty percent, with a local maximum between about (±5°) 105° and 135°. Thus, within the computed range, an obtuse angle between beveled segments of about 105° and 135° are expected to provide a particularly beneficial increase of isolation device performance and reliability, with obtuse angles between 105° and 135° providing lesser but significant improvement relative to the right angle value representative of conventional designs.

What is claimed is:

1. A microelectronic device, comprising:
a substrate;
a dielectric layer including a first surface at a first height over the substrate, a second surface at a second height over the substrate, and a third surface connecting the first surface and the second surface, the first and third surfaces forming a beveled corner; and
a beveled interconnect including a first interconnect segment over the first surface and a second interconnect segment extending from the first interconnect segment toward the second surface and ending over the third surface.

2. The microelectronic device of claim 1, wherein the dielectric layer includes a fourth surface at the second height above the substrate and a fifth surface connecting the first surface and the fourth surface, and the beveled interconnect includes a third interconnect segment that extends from the first interconnect segment toward the fifth surface and ends over the fourth surface.

3. The microelectronic device of claim 1, wherein a sidewall surface of the second interconnect segment forms a sidewall angle with the third surface that is greater than ninety degrees.

4. The microelectronic device of claim 3, wherein the sidewall angle is in a range from 100° to 140°.

5. The microelectronic device of claim 3, wherein the sidewall angle is 105°±5°.

6. The microelectronic device of claim 3, wherein the sidewall angle is 135°±5°.

7. The microelectronic device of claim 3, wherein the sidewall surface is a first sidewall surface, the sidewall angle is a first sidewall angle, and a third interconnect segment extends from the first interconnect segment, the third interconnect segment having a second sidewall that forms a second sidewall angle with a third bottom surface of the third interconnect segment, the second sidewall angle greater than ninety degrees.

8. The microelectronic device of claim 1, including an isolation device over the substrate, the isolation device including:
a lower isolation element; and
an upper isolation element over the lower isolation element, the upper isolation element including the beveled interconnect.

9. The microelectronic device of claim 1, wherein the dielectric layer is a first dielectric layer in contact with a second dielectric layer and the beveled corner is a first beveled corner, the first beveled corner over a second beveled corner in the second dielectric layer.

10. The microelectronic device of claim 1, wherein the first surface is a top surface of a beveled dielectric recess region that includes a plurality of interconnect line segments.

11. The microelectronic device of claim 1, wherein the beveled interconnect is a portion of a coil of an inductive isolator.

12. The microelectronic device of claim 1, wherein the beveled interconnect is a capacitor plate of an isolation capacitor.

13. A method of forming a microelectronic device, comprising:
forming a dielectric layer over a substrate, the dielectric layer having a first surface at a first height over the substrate, a second surface at a second height over the substrate, and a third surface connecting the first surface and the second surface, the first and third surfaces forming a beveled corner; and
forming a beveled interconnect including a first interconnect segment over the first surface and a second interconnect segment extending from the first interconnect segment toward the second surface and ending over the third surface.

14. The method of claim 13, wherein the second interconnect segment has a sidewall surface that forms a sidewall angle with the third surface that is in a range from 100° to 140°.

15. The method of claim 13, wherein forming the third surface includes greyscale lithography.

16. The method of claim 13, wherein the dielectric layer includes a fourth surface at the second height above the substrate and a fifth surface connecting the first surface and the fourth surface, and the beveled interconnect includes a third segment that extends from the first interconnect segment toward the fifth surface and ends over the fourth surface.

17. The method of claim 13, wherein the beveled interconnect is a first beveled interconnect and the dielectric layer includes a fourth surface at the second height above the substrate and a fifth surface connecting the first surface and the fourth surface, and further comprising forming a second beveled interconnect including a third interconnect segment over the first surface and a fourth interconnect segment extending from the third interconnect segment toward the fifth surface and ending over the fourth surface.

18. The method of claim 17, further comprising forming a non-beveled interconnect on the first surface between the first and second beveled interconnects.

19. The method of claim 13, wherein the beveled interconnect is a portion of a coil of an inductive isolator.

20. The method of claim 13, wherein the beveled interconnect is a capacitor plate of an isolation capacitor.
